(19) United States
(12) Patent Application Publication
(10) Pub. No.: US 2011/0061727 A1
(43) Pub. Date: Mar. 17, 2011

(54) DYE-SENSITIZED SOLAR CELLS AND MOBILE DEVICE INCLUDING THE SAME

(75) Inventors: Woon-Chun KIM, Suwon-si (KR); Hyun-Seop Shim, Incheon-si (KR); Soon-Gyu Yim, Seongnam-si (KR)

(73) Assignee: SAMSUNG ELECTRO-MECHANICS CO., LTD.

(21) Appl. No.: 12/650,236

(22) Filed: Dec. 30, 2009

(30) Foreign Application Priority Data
Sep. 15, 2009 (KR) 10-2009-0086934

(51) Int. Cl. H01L 31/00

(52) U.S. Cl. 136/256

(57) ABSTRACT

A dye-sensitized solar cell is disclosed. The dye-sensitized solar cell includes a first substrate, being transparent, a first electrode, formed on a rear surface of the first substrate, a second electrode, formed apart from the first electrode, a catalytic layer, formed on a rear surface of the first electrode, a light absorption layer, which is formed on a front surface of the second electrode and includes a dye absorbed into metal oxide such that the dye forms a specific pattern with the metal oxide, an electrolyte, interposed between the first electrode and the second electrode, a base layer, which is formed on a rear surface of the second electrode and forms a background against the pattern formed by the dye such that the pattern can be identified when viewed from the outside, and a second substrate, formed on a rear surface of the base layer.

### CROSS-REFERENCE TO RELATED APPLICATIONS

This application claims the benefit of Korean Patent Application No. 10-2009-0086934, filed with the Korean Intellectual Property Office on Sep. 15, 2009, the disclosure of which is incorporated herein by reference in its entirety.

### BACKGROUND

1. Technical Field

The present invention relates to a dye-sensitized solar cell and a mobile phone including the same.

2. Description of the Related Art

A solar cell, which generates electric energy by using solar energy, provides infinite energy and is durable and environmentally friendly. Some examples of solar cells include silicon solar cells, semiconductor compound solar cells and dye-sensitized solar cells.

Here, the dye-sensitized solar cell is a solar cell in which a dye molecule interposed between a pair of electrodes converts sunlight to electrons by absorbing the sunlight.

The dye-sensitized solar cell can form a specific pattern that can be viewed from the outside by properly disposing dye molecules. Nevertheless, the pattern may not be identified from the outside by external factors such as the viewing angle.

### SUMMARY

The present invention provides a dye-sensitized solar cell that can effectively identify a specific pattern formed by a dye when viewed from the outside, and a mobile device including the same.

An aspect of the present invention provides a dye-sensitized solar cell that includes a first substrate, which is transparent, a first electrode, which is formed on a rear surface of the first substrate, a second electrode, which is formed apart from the first electrode and in which the second electrode faces the first electrode, a catalytic layer, which is formed on a rear surface of the first electrode, a light absorption layer, which is formed on a front surface of the second electrode and includes a dye which is absorbed into metal oxide such that the dye forms a specific pattern with the metal oxide, an electrolyte, which is interposed between the first electrode and the second electrode, a base layer, which is formed on a rear surface of the second electrode and forms a background against the pattern formed by the dye such that the pattern can be identified when viewed from the outside, and a second substrate, which is formed on a rear surface of the base layer.

The base layer can be formed by including a fluorescent or phosphorescent substance.

The base layer can be translucent, and the second substrate can be a metal substrate having a reflective surface formed on its front surface.

The dye-sensitized solar cell can further include a secondary base layer, which is formed on a rear surface of the second substrate. Here, the base layer can be translucent, and the second substrate can be transparent.

The secondary base layer can be formed by including a fluorescent or phosphorescent substance.

The secondary base layer can be formed by including a dye or pigment with a specific color.

The dye-sensitized solar cell can further include a metal coating layer, which is interposed between the base layer and the second substrate and provides a reflective surface. Here, the base layer can be translucent.

The dye-sensitized solar cell can further include a metal coating layer, which is formed on a rear surface of the second substrate and provides a reflective surface. Here, the base layer can be translucent, and the second substrate can be transparent.

The base layer can be formed by including a dye or pigment with a specific color.

The base layer can be translucent, and the second substrate can be a metal substrate having a reflective surface formed on its front surface.

The dye-sensitized solar cell can further include a secondary base layer, which is formed on a rear surface of the second substrate. Here, the base layer can be translucent, and the second substrate can be transparent.

The secondary base layer can be formed by including a fluorescent or phosphorescent substance.

The secondary base layer can be formed by including a dye or pigment with a specific color.

The dye-sensitized solar cell can further include a metal coating layer, which is interposed between the base layer and the second substrate and provides a reflective surface. Here, the base layer can be translucent.

The dye-sensitized solar cell can further include a metal coating layer, which is formed on a rear surface of the second substrate and provides a reflective surface. Here, the base layer can be translucent, and the second substrate can be transparent.

Another aspect of the present invention provides a dye-sensitized solar cell that includes a first substrate, which is transparent, a first electrode, which is formed on a rear surface of the first substrate, a second electrode, which is formed apart from the first electrode and in which the second electrode faces the first electrode, a light absorption layer, which is formed on a rear surface of the first electrode and in which the light absorption layer includes a dye which is absorbed into metal oxide such that the dye forms a specific pattern with the metal oxide, a catalytic layer, which is formed on a front surface of the second electrode, an electrolyte, which is interposed between the first electrode and the second electrode, a base layer, which is formed on a rear surface of the second electrode and forms a background against the pattern formed by the dye such that the pattern can be identified when viewed from the outside, and a second substrate, which is formed on a rear surface of the base layer.

The base layer can be formed by including a dye or pigment with a specific color.

The base layer can be translucent, and the second substrate can be a metal substrate having a reflective surface formed on its front surface.

The dye-sensitized solar cell can further include a secondary base layer, which is formed on a rear surface of the second substrate. Here, the base layer can be translucent, and the second substrate can be transparent.

The secondary base layer can be formed by including a fluorescent or phosphorescent substance.

The secondary base layer can be formed by including a dye or pigment with a specific color.

The dye-sensitized solar cell can further include a metal coating layer, which is interposed between the base layer and the second substrate and provides a reflective surface. Here, the base layer can be translucent.

The dye-sensitized solar cell can further include a metal coating layer, which is formed on a rear surface of the second substrate and provides a reflective surface. Here, the base layer can be translucent, and the second substrate can be transparent.

Another aspect of the present invention provides a dye-sensitized solar cell that includes a first substrate, which is transparent, a first electrode, which is formed on a rear surface of the first substrate, a second electrode, which is formed apart from the first electrode and in which the second electrode faces the first electrode, a light absorption layer, which is interposed between the first electrode and the second electrode and in which the light absorption layer includes a dye which is absorbed into metal oxide such that the dye forms a specific pattern with the metal oxide, a catalytic layer, which is interposed between the first electrode and the second electrode and in which the catalytic layer is formed apart from the light absorption layer and the catalytic layer faces the light absorption layer, an electrolyte, which is interposed between the first electrode and the second electrode, and a second substrate, which is formed on a rear surface of the second electrode and forms a background against the pattern formed by the dye such that the pattern can be identified when viewed from the outside.

The second substrate is a metal substrate and can have a colored reflective surface formed on its front surface.

Another aspect of the present invention provides a dye-sensitized solar cell that includes a first substrate, which is transparent, a first electrode, which is formed on a rear surface of the first substrate, a second electrode, which is formed apart from the first electrode and in which the second electrode faces the first electrode, a catalytic layer, which is formed on a rear surface of the first electrode, a light absorption layer, which is formed on a front surface of the second electrode and in which the light absorption layer includes a dye which is absorbed into metal oxide such that the dye forms a specific pattern with the metal oxide, an electrolyte, which is interposed between the first electrode and the second electrode, a second substrate, which is formed on a rear surface of the second electrode and in which the second substrate is transparent, and a base layer, which is formed on a rear surface of the second electrode and forms a background against the pattern formed by the dye such that the pattern can be identified when viewed from the outside.

The base layer can be formed by including a fluorescent or phosphorescent substance.

The base layer can be formed by including a dye or pigment with a specific color.

Another aspect of the present invention provides a dye-sensitized solar cell that includes a first substrate, which is transparent, a first electrode, which is formed on a rear surface of the first substrate, a second electrode, which is formed apart from the first electrode and in which the second electrode faces the first electrode, a light absorption layer, which is formed on a rear surface of the first electrode and in which the light absorption layer includes a dye which is absorbed into metal oxide such that the dye forms a specific pattern with the metal oxide, a catalytic layer, which is formed on a front surface of the second electrode, an electrolyte, which is interposed between the first electrode and the second electrode, a second substrate, which is formed on a rear surface of the second electrode and in which the second substrate is transparent, and a base layer, which is formed on a rear surface of the second electrode and forms a background against the pattern formed by the dye such that the pattern can be identified when viewed from the outside.

The base layer can be formed by including a dye or pigment with a specific color.

Another aspect of the present invention provides a mobile device that includes a body and the above dye-sensitized solar cell, which is mounted on the body.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 briefly shows a structure of a dye-sensitized solar cell in accordance with an embodiment of the present invention.

FIG. 2 shows a pattern formed by a dye included in a dye-sensitized solar cell in accordance with an embodiment of the present invention.

FIGS. 3 to 12 briefly show a respective structure of a dye-sensitized solar cell in accordance with different embodiments of the present invention.

### DETAILED DESCRIPTION

Certain embodiments of the present invention will be described below in more detail with reference to the accompanying drawings. Those components that are the same or are in correspondence are rendered the same reference numeral regardless of the figure number, and redundant descriptions are omitted.

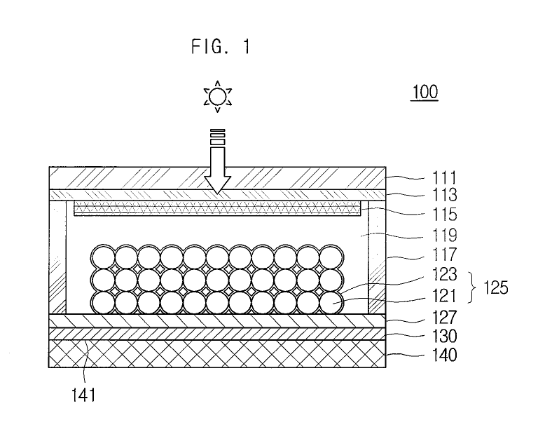

FIG. 1 briefly shows a structure of a dye-sensitized solar cell in accordance with an embodiment of the present invention. Referring to FIG. 1, a dye-sensitized solar cell 100 according to the present embodiment can be constituted by a first substrate 111, a first electrode 113, a second electrode 127, a catalytic layer 115, a light absorption layer 125, an electrolyte 119, a base layer 130 and a second substrate 140.

The first substrate 111 is transparent and can allow a ray of sunlight incident from the front to pass through. The first substrate 111 can be made of glass or high polymer such as PET.

The first electrode 113 can be formed on a rear surface of the first substrate 111. The second electrode 127 can be formed apart from the first electrode 113, facing the first electrode 113. The first electrode 113 and the second electrode 127 can each be formed by including Indium Tin Oxide (ITO), Fluorine-doped Tin Oxide (FTO), Carbon Nano Tube (CNT) or Graphene. The first electrode 113 and the second electrode 127 can have conductivity. The first electrode 113 and the second electrode 127 can be transparent.

The catalytic layer 115 can be formed on a rear surface of the first electrode 113. The catalytic layer 115 can be formed by including platinum (Pt), carbon, Carbon Nano Tube (CNT) or Graphene.

Referring to FIG. 1, the light absorption layer 125 can be formed on a front surface of the second electrode 127. The light absorption layer 125 can be formed by including metal oxide 121 and a dye 123, which is absorbed into the metal oxide 121. When the sunlight is absorbed in the dye 123, the dye 123 transfers electrons from a ground state to an excited state. The excited state electron is injected into a conduction band of an interface between particles of the metal oxide 121, and the injected electron is transferred to the first electrode 113 along the interface between particles of the metal oxide 121 and is moved to the second electrode 127 through an external circuit (not shown).

The dye 123, which is oxidized by electronic transmission, can be deoxidized by an iodine oxidation-reduction pair (I₃⁻/I⁻) in an electrolyte 119, which will be described later. The oxidized iodine oxidation-reduction pair makes a reduction reaction with electrons arrived at an interface of the second electrode 127 to achieve charge neutrality so that the dye-sensitized solar cell can be operated.

In this embodiment, the dye 123 included in the light absorption layer 125 forms a specific pattern. Here, the pattern encompasses a shape formed by disposing the dye and a color of the dye, and the specific pattern is a pattern that is predetermined when the dye-sensitized solar cell is manufactured.

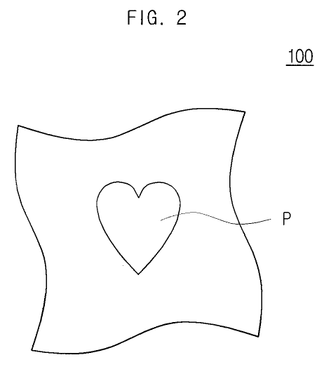

FIG. 2 shows a pattern formed by a dye included in a dye-sensitized solar cell in accordance with an embodiment of the present invention. Referring to FIG. 2, the dye-sensitized solar cell 100 of the present embodiment can have the color of, for example, red (not shown) by the dye 123 (refer to FIG. 1) when viewed from the front and can form a specific pattern P formed in the shape of a heart.

Meanwhile, the electrolyte 129 can be interposed between the first electrode 113 and the second electrode 127. The electrolyte 119 can be made of an iodine oxidation-reduction liquid electrolyte, that is, an electrolyte aqueous solution of I₃⁻/I⁻ in which 1-vinyl-3-methyl-imidazolium iodide, 0.1 mol LiI, 40 m-mol I₂ (iodine) and 0.2 mol tert-butyl pyridine are dissolved in 3-methoxypropionitrile. However, the electrolyte 119 is not limited to this example.

The electrolyte 119 can be sealed by a partition wall 117 that is interposed between the first electrode 113 and the second electrode 127. The partition wall 117 can be made of, for example, a thermoplastic high polymer membrane such as Surlyn and can have a thickness of about 30˜50 μm and a width of about 1˜4 mm.

In this embodiment, the base layer 130 can be formed on a rear surface of the second electrode 127. The base layer 130 forms a background against a pattern formed by the dye 123 such that the pattern can be effectively identified when viewed from the outside.

The base layer 130 can be formed by including a fluorescent or phosphorescent substance. The base layer 130 can absorb the sunlight transmitted through the second electrode 127 and can emit light. In this case, the light-emitting base layer 130 is disposed behind the light absorption layer 125, and thus the light-emitting base layer 130 forms a background against the pattern formed by the dye 123 when viewed from the front of the first substrate 111. In this way, the pattern, formed by the dye 123, on the base layer 130 that functions as a background can be effectively identified from the outside.

Particularly, if the base layer 130 is made of a phosphorescent material, the light-emitting base layer 130 that is exposed to sunlight can emit light for a certain period of time even in a dark space so that the pattern formed by the dye 123 can be effectively seen in the dark space.

Furthermore, since the light-emitting base layer 130 is disposed adjacent to the light absorption layer 125, the light emitted by the base layer 130 can directly reach the dye 123 so that the pattern formed by the dye 123 can be identified more clearly from the outside.

Meanwhile, the base layer 130 can be formed by including a dye or pigment with a specific color, instead of a fluorescent or phosphorescent material. Here, the specific color is the color of a background against a pattern formed by the dye 123 included in the light absorption layer 125 to make the pattern stand out.

In one example, the base layer 130 can be formed by including a dye or pigment with the color of white or pale yellow. Since the base layer 130 including a dye or pigment with such specific color is disposed behind the light absorption layer 125, the pattern formed by the dye 123 can be effectively identified against its background when viewed from the front of the first substrate 111.

In this embodiment, the second substrate 140 can be formed on a rear surface of the base layer 130. The second substrate 140 supports other components of the dye-sensitized solar cell 100.

The second substrate 140 can be a metal substrate having a reflective surface 141 formed thereon. In this case, it is preferable that the base layer 130 is translucent. To make the base layer 130 translucent, the base layer 130 can be formed in the shape of a thin-film or the concentration of a fluorescent substance included in the base layer 130 can be lowered.

In this case, a portion of the sunlight transmitted through the second electrode 127 transmits through the translucent base layer 130. The sunlight transmitted through the base layer 130 can be reflected to the base layer 130 by the reflective surface 141 of the second substrate 140.

The light reflected by the second substrate 140 strikes a rear surface of the translucent base layer 130 so that the base layer 130 can be identified more clearly when viewed from the outside. This allows the pattern formed by the dye 123 to be identified more clearly.

While this embodiment presents an example in which the second substrate 140 is a metal substrate and the base layer 130 is translucent, it shall be apparent that a second substrate of various materials and shapes and an opaque base layer can be employed.

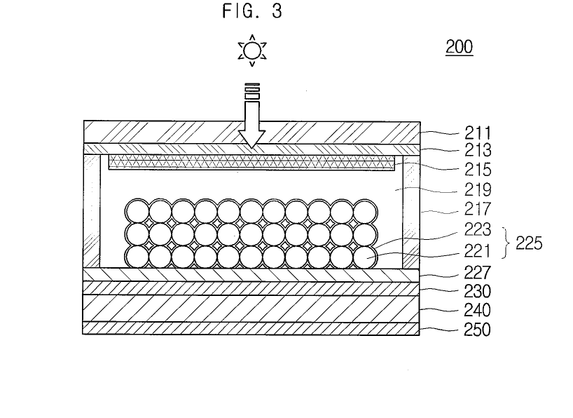

FIG. 3 briefly shows a structure of a dye-sensitized solar cell in accordance with another embodiment of the present invention. Referring to FIG. 3, a dye-sensitized solar cell 200 according to the present embodiment can be constituted by a first substrate 211, a first electrode 213, a second electrode 227, a catalytic layer 215, a light absorption layer 225, an electrolyte 219, a base layer 230, a second substrate 240 and a secondary base layer 250.

Compared to the dye-sensitized solar cell 100 of the previously described embodiment, the dye-sensitized solar cell 200 of the present embodiment further includes the secondary base layer 250, which is formed on a rear surface of the second substrate 240. Thus, the difference between the dye-sensitized solar cell 200 of the present embodiment and the dye-sensitized solar cell 100 of the previously described embodiment will be mainly described hereinafter, and redundant descriptions are omitted.

In this embodiment, the base layer 230 forms a background against a pattern formed by a dye 223 such that the pattern can be effectively identified when viewed from the outside and can be formed by including a fluorescent or phosphorescent substance or by including a dye or pigment with a specific color. In this case, the base layer 230 can be translucent.

The second substrate 240 can be formed on a rear surface of the base layer 230. In this case, the second substrate 240 is a transparent substrate and can be made of glass or high polymer.

The secondary base layer 250 can be formed on a rear surface of the second substrate 240. The secondary base layer 250 with the base layer 230 forms a background against the pattern formed by the dye 223.

More specifically, the secondary base layer 250 can be formed by including a fluorescent or phosphorescent substrate. In this case, the secondary base layer 250 can absorb the sunlight transmitted through the transparent second substrate 240 after having passed through the translucent base layer 230 and can emit light.

Since light is emitted from the secondary base layer 250 located at the bottom of the translucent base layer 230, the secondary base layer 250 forms a background against a pattern formed by the dye 223 with the base layer 230 such that the pattern can be effectively identified when viewed from the front of the first substrate 211.

Meanwhile, the secondary base layer 250 can be formed by including a dye or pigment with a specific color. Here, the specific color is the color of a background against a pattern formed by the dye 223 included in the light absorption layer 225 to make the pattern stand out. In one example, the secondary base layer 250 can be formed by including a dye or pigment with white or pale yellow color.

Since the secondary base layer 250 is disposed behind the translucent base layer 230, the secondary base layer 250 forms a background with the base layer 230 that allows the pattern formed by the dye 223 to be effectively identified when viewed from the front of the first substrate 211.

Meanwhile, the dye-sensitized solar cell 200 of the present embodiment can further include a metal coating layer (not shown), which is formed on a rear surface of the secondary base layer 250 and provides a reflective surface. In this case, the secondary base layer 250 can be translucent.

The sunlight transmitted through the translucent secondary base layer 250 can be reflected to the secondary base layer 250 by the metal coating layer (not shown). The light reflected by the metal coating layer (not shown) strikes a rear surface of the translucent base layer 230 and the translucent secondary base layer 250 so that the base layer 230 and the secondary base layer 250 can be identified more clearly when viewed from the outside. This allows the pattern formed by the dye 223 to be identified more clearly.

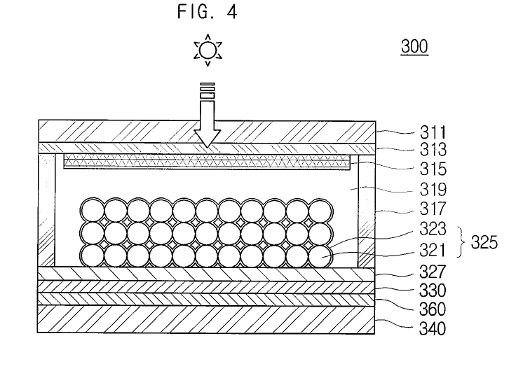

FIG. 4 briefly shows a structure of a dye-sensitized solar cell in accordance with yet another embodiment of the present invention. Referring to FIG. 4, a dye-sensitized solar cell 300 according to the present embodiment can be constituted by a first substrate 311, a first electrode 313, a second electrode 327, a catalytic layer 315, a light absorption layer 325, an electrolyte 319, a base layer 330, a second substrate 340 and a metal coating layer 360.

Compared to the dye-sensitized solar cell 100 of the previously described embodiment, the dye-sensitized solar cell 300 of the present embodiment further includes the metal coating layer 360, which is interposed between the base layer 330 and the second substrate 340. Thus, the difference between the dye-sensitized solar cell 300 of the present embodiment and the dye-sensitized solar cell 100 of the previously described embodiment will be mainly described hereinafter, and redundant descriptions are omitted.

In this embodiment, the base layer 330 forms a background against a pattern formed by a dye 323 such that the pattern can be effectively identified when viewed from the outside and can be formed by including a fluorescent or phosphorescent substance or by including a dye or pigment with a specific color. In this case, the base layer 330 can be translucent.

The metal coating layer 360 can be interposed between the base layer 330 and the second substrate 340. The metal coating layer 360 forms a reflective surface. In this case, the light transmitted through the translucent base layer 330 can be reflected to the base layer 330 by the reflective surface of the metal coating layer 360.

The light reflected by the metal coating layer 360 strikes a rear surface of the translucent base layer 330 so that the base layer 330 can be identified more clearly when viewed from the outside. This allows the pattern formed by the dye 323 to be identified more clearly.

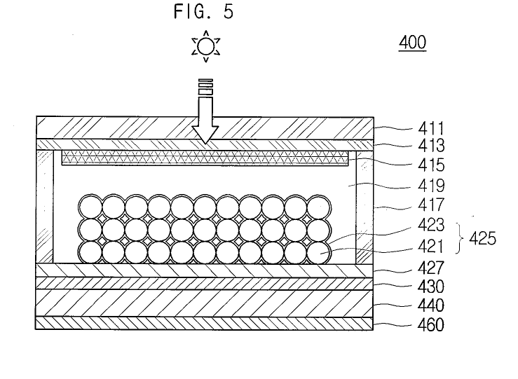

FIG. 5 briefly shows a structure of a dye-sensitized solar cell in accordance with still another embodiment of the present invention. Referring to FIG. 5, a dye-sensitized solar cell 400 according to the present embodiment can be constituted by a first substrate 411, a first electrode 413, a second electrode 427, a catalytic layer 415, a light absorption layer 425, an electrolyte 419, a base layer 430, a second substrate 440 and a metal coating layer 460.

Compared to the dye-sensitized solar cell 100 of the previously described embodiment, the dye-sensitized solar cell 400 of the present embodiment further includes the metal coating layer 460, which is formed on a rear surface of the second substrate 440. Thus, the difference between the dye-sensitized solar cell 400 of the present embodiment and the dye-sensitized solar cell 100 of the previously described embodiment will be mainly described hereinafter, and redundant descriptions are omitted.

In this embodiment, the base layer 430 forms a background against a pattern formed by a dye 423 such that the pattern can be effectively identified when viewed from the outside and can be formed by including a fluorescent or phosphorescent substance or by including a dye or pigment with a specific color. In this case, the base layer 430 can be translucent.

In this embodiment, the second substrate 440 can be formed on a rear surface of the base layer 430. In this case, the second substrate 440 can be a transparent substrate.

The metal coating layer 460 can be disposed on a rear surface of the transparent second substrate 440. The metal coating layer 460 forms a reflective surface. In this case, the light transmitted through the transparent second substrate 440 after having passed the translucent base layer 430 can be reflected to the base layer 430 by the metal coating layer 460.

The light reflected by the metal coating layer 460 strikes a rear surface of the translucent base layer 430 so that the base layer 430 can be identified more clearly when viewed from the outside. This allows the pattern formed by the dye 423 to be identified more clearly.

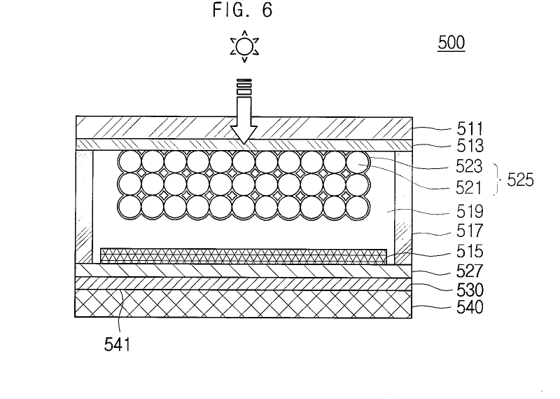

FIG. 6 briefly shows a structure of a dye-sensitized solar cell in accordance with still another embodiment of the present invention. Referring to FIG. 6, a dye-sensitized solar cell 500 according to the present embodiment can be constituted by a first substrate 511, a first electrode 513, a second electrode 527, a catalytic layer 515, a light absorption layer 525, an electrolyte 519, a base layer 530 and a second substrate 540.

Compared to the dye-sensitized solar cell 100 of the previously described embodiment, the dye-sensitized solar cell 500 of the present embodiment is different in that the positions of the catalytic layer 515 and the light absorption layer 525 are different from those of the catalytic layer 115 and the light absorption layer 125 of the dye-sensitized solar cell 100 of the previously described embodiment. Thus, the difference between the dye-sensitized solar cell 500 of the present embodiment and the dye-sensitized solar cell 100 of the previously described embodiment will be mainly described hereinafter, and redundant descriptions are omitted.

In this embodiment, the catalytic layer 515 is formed on a front surface of the second electrode 527, and the light absorption layer 525 is disposed on a rear surface of the first electrode 513. In this case, the base layer 530 can be formed on a rear surface of the second electrode 527.

The base layer 530 forms a background against a pattern formed by a dye 523 such that the pattern can be effectively identified when viewed from the outside and can be formed by including a fluorescent or phosphorescent substance or by including a dye or pigment with a specific color.

In this embodiment, the second substrate 540 can be formed on a rear surface of the base layer 530. The second substrate 540 supports other components of the dye-sensitized solar cell 500.

The second substrate 540 can be a metal substrate having a reflective surface 541 formed thereon. In this case, it is preferable that the base layer 530 is translucent. In this case, a portion of the sunlight transmitting through the second electrode 527 transmits through the translucent base layer 530. The sunlight transmitted through the base layer 530 can be reflected to the base layer 530 by the reflective surface 541 of the second substrate 540.

The light reflected by the second substrate 540 strikes a rear surface of the translucent base layer 530 so that the base layer 530 can be identified more clearly when viewed from the outside. This allows the pattern formed by the dye 523 to be identified more clearly.

While this embodiment presents an example in which the second substrate 540 is a metal substrate and the base layer 530 is translucent, it shall be apparent that a second substrate of various materials and shapes and an opaque base layer can be employed.

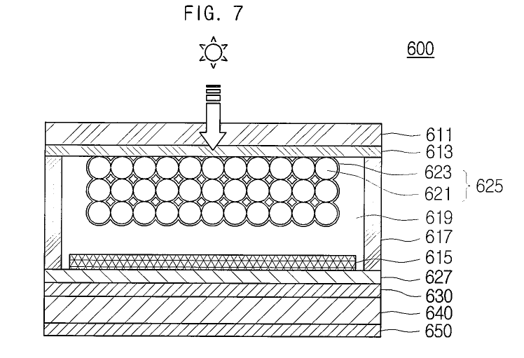

FIG. 7 briefly shows a structure of a dye-sensitized solar cell in accordance with still another embodiment of the present invention. Referring to FIG. 7, a dye-sensitized solar cell 600 according to the present embodiment can be constituted by a first substrate 611, a first electrode 613, a second electrode 627, a catalytic layer 615, a light absorption layer 625, an electrolyte 619, a base layer 630, a second substrate 640 and a secondary base layer 650.

Compared to the dye-sensitized solar cell 200 of the previously described embodiment, the dye-sensitized solar cell 600 of the present embodiment is different in that the positions of the catalytic layer 615 and the light absorption layer 625 are different from those of the catalytic layer 215 and the light absorption layer 225 of the dye-sensitized solar cell 200 of the previously described embodiment. Thus, the difference between the dye-sensitized solar cell 600 of the present embodiment and the dye-sensitized solar cell 200 of the previously described embodiment will be mainly described hereinafter, and redundant descriptions are omitted.

In this embodiment, the base layer 630 forms a background against a pattern formed by a dye 623 such that the pattern can be effectively identified when viewed from the outside and can be formed by including a fluorescent or phosphorescent substance or by including a dye or pigment with a specific color. In this case, the base layer 630 can be translucent. The transparent second substrate 640 can be formed on a rear surface of the translucent base layer 630. The secondary base layer 650 can be formed on a rear surface of the transparent second substrate 640. The secondary base layer 650 forms a background with the base layer 630 against the pattern formed by the dye 623.

The secondary base layer 650 can be formed by including a fluorescent or phosphorescent substance or by including a dye or pigment with a specific color. Since the secondary base layer 650 is disposed with the translucent base layer 630 behind the light absorption layer 625, the secondary base layer 650 forms a background with the base layer 630 that allows the pattern formed by the dye 623 to be effectively identified when viewed from the front of the first substrate 611.

Meanwhile, the dye-sensitized solar cell 600 of the present embodiment can further include a metal coating layer (not shown), which is formed on a rear surface of the secondary base layer 650 and provides a reflective surface. In this case, the secondary base layer 650 can be translucent.

In this case, the sunlight transmitted through the translucent secondary base layer 650 can be reflected to the secondary base layer 650 by the metal coating layer (not shown). The light reflected by the metal coating layer (not shown) strikes a rear surface of the translucent base layer 630 and the translucent secondary base layer 650 so that the base layer 630 and the secondary base layer 650 can be identified more clearly when viewed from the outside. This allows the pattern formed by the dye 623 to be identified more clearly.

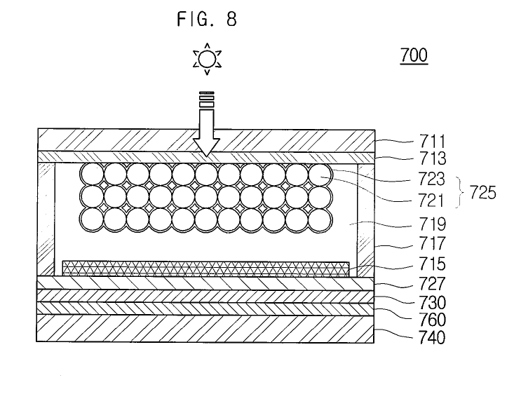

FIG. 8 briefly shows a structure of a dye-sensitized solar cell in accordance with still another embodiment of the present invention. Referring to FIG. 8, a dye-sensitized solar cell 700 according to the present embodiment can be constituted by a first substrate 711, a first electrode 713, a second electrode 727, a catalytic layer 715, a light absorption layer 725, an electrolyte 719, a base layer 730, a second substrate 740 and a metal coating layer 760.

Compared to the dye-sensitized solar cell 300 of the previously described embodiment, the dye-sensitized solar cell 700 of the present embodiment is different in that the positions of the catalytic layer 715 and the light absorption layer 725 are different from those of the catalytic layer 315 and the light absorption layer 325 of the dye-sensitized solar cell 300 of the previously described embodiment. Thus, the difference between the dye-sensitized solar cell 700 of the present embodiment and the dye-sensitized solar cell 300 of the previously described embodiment will be mainly described hereinafter, and redundant descriptions are omitted.

In this embodiment, the base layer 730 forms a background against a pattern formed by a dye 723 such that the pattern can be effectively identified when viewed from the outside and can be formed by including a fluorescent or phosphorescent substance or by including a dye or pigment with a specific color. In this case, the base layer 730 can be translucent.

In this embodiment, the metal coating layer 760 can be interposed between the translucent base layer 730 and the second substrate 740. The metal coating layer 760 forms a reflective surface. In this case, the light transmitted through the translucent base layer 730 can be reflected to the base layer 730 by the reflective surface of the metal coating layer 760.

The light reflected by the metal coating layer 760 strikes a rear surface of the translucent base layer 730 so that the base layer 730 can be identified more clearly when viewed from the outside. This allows the pattern formed by the dye 723 to be identified more clearly.

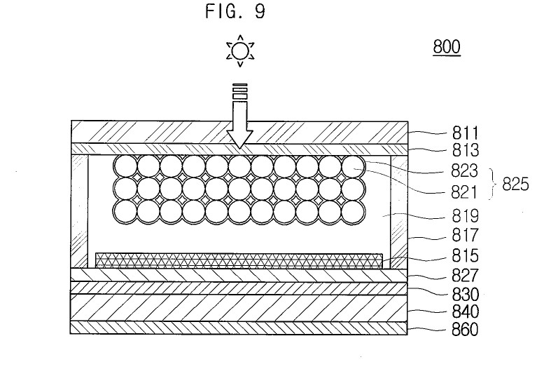

FIG. 9 briefly shows a structure of a dye-sensitized solar cell in accordance with still another embodiment of the present invention. Referring to FIG. 9, a dye-sensitized solar cell 800 according to the present embodiment can be constituted by a first substrate 811, a first electrode 813, a second electrode 827, a catalytic layer 815, a light absorption layer 825, an electrolyte 819, a base layer 830, a second substrate 840 and a metal coating layer 860.

Compared to the dye-sensitized solar cell 400 of the previously described embodiment, the dye-sensitized solar cell 800 of the present embodiment is different in that the positions of the catalytic layer 815 and the light absorption layer 825 are different from those of the catalytic layer 415 and the light absorption layer 425 of the dye-sensitized solar cell 400 of the previously described embodiment. Thus, the difference between the dye-sensitized solar cell 800 of the present embodiment and the dye-sensitized solar cell 400 of the previously described embodiment will be mainly described hereinafter, and redundant descriptions are omitted.

In this embodiment, the base layer 830 forms a background against a pattern formed by a dye 823 such that the pattern can be effectively identified when viewed from the outside and can be formed by including a fluorescent or phosphorescent substance or by including a dye or pigment with a specific color. In this case, the base layer 830 can be translucent.

In this embodiment, the second substrate 840 can be formed on a rear surface of the translucent base layer 830. In this case, the second substrate 840 can be a transparent substrate.

The metal coating layer 860 can be disposed on a rear surface of the transparent second substrate 840. The metal coating layer 860 forms a reflective surface. In this case, the light transmitted through the transparent second substrate 840 after having passed the translucent base layer 830 can be reflected to the base layer 830 by the metal coating layer 860.

The light reflected by the metal coating layer 860 strikes a rear surface of the translucent base layer 830 so that the base layer 830 can be identified more clearly when viewed from the outside. This allows the pattern formed by the dye 823 to be identified more clearly.

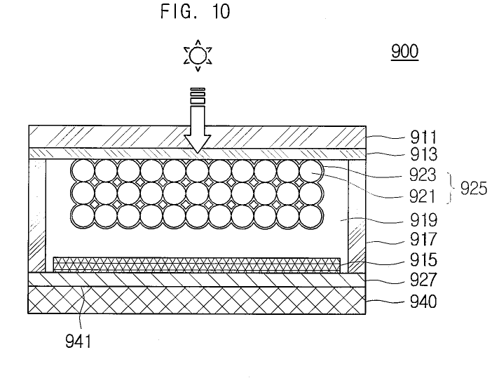

FIG. 10 briefly shows a structure of a dye-sensitized solar cell in accordance with still another embodiment of the present invention. Referring to FIG. 10, a dye-sensitized solar cell 900 according to the present embodiment can be constituted by a first substrate 911, a first electrode 913, a second electrode 927, a catalytic layer 915, a light absorption layer 925, an electrolyte 919 and a second substrate 940.

In the description of the dye-sensitized solar cell 900 according to the present embodiment, certain detailed descriptions of the previously described embodiments will be omitted.

In this embodiment, the catalytic layer 915 and the light absorption layer 925 can be interposed between the first electrode 913 and the second electrode 927. In this case, as illustrated in FIG. 10, the light absorption layer 925 can be formed on a rear surface of the first electrode 913, and the catalytic layer 915 can be formed on a front surface of the second electrode 927.

Although the light absorption layer 925 and the catalytic layer 915 are formed on a rear surface of the first electrode 913 and a front surface of the second electrode 927, respectively, this configuration is only one example, and the light absorption layer 925 and the catalytic layer 915 can be formed on the front surface of the second electrode 927 and the rear surface of the first electrode 913, respectively.

The second substrate 940 can be disposed on a rear surface of the second electrode 927. In this embodiment, the second substrate 940 forms a background against a pattern formed by a dye 923 such that the pattern can be effectively identified when viewed from the outside.

The second substrate 940 can have a specific color. Here, the specific color is the color of a background against a pattern formed by the dye 923 included in the light absorption layer 925 to make the pattern stand out. In one example, the second substrate 940 can have white or pale yellow color.

In this embodiment, since the second substrate 940 with a specific color is disposed behind the light absorption layer 925, the pattern formed by the dye 923 can be effectively identified against its background when viewed from the front of the first substrate 911.

Meanwhile, the second substrate 940 can be a metal substrate. In this case, the second substrate 940 can have a colored reflective surface 941 formed on its front surface. The Femto pulse laser can be used to color the reflective surface 941. The color of the reflective surface 941 is the color of a background against the pattern formed by the dye 923. The reflective surface 941 of the second substrate 940 reflects light to the light absorption layer 925 and also forms a background against the pattern of the dye 923, and thus the pattern formed by the dye 923 can be effectively identified when viewed from the front of the first substrate 911.

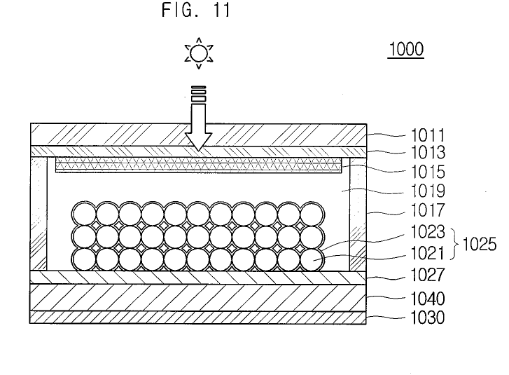

FIG. 11 briefly shows a structure of a dye-sensitized solar cell in accordance with still another embodiment of the present invention. Referring to FIG. 11, a dye-sensitized solar cell 1000 according to the present embodiment can be constituted by a first substrate 1011, a first electrode 1013, a second electrode 1027, a catalytic layer 1015, a light absorption layer 1025, an electrolyte 1019, a second substrate 1040 and a base layer 1030.

Compared to the dye-sensitized solar cell 100 of the previously described embodiment, the dye-sensitized solar cell 1000 of the present embodiment is different in that the positions of the second substrate 1040 and the base layer 1030 are different from those of the second substrate 140 and the base layer 130 of the dye-sensitized solar cell 100 of the previously described embodiment. Thus, the difference between the dye-sensitized solar cell 1000 of the present embodiment and the dye-sensitized solar cell 100 of the previously described embodiment will be mainly described hereinafter, and redundant descriptions are omitted.

In this embodiment, the second substrate 1040 can be formed on a rear surface of the second electrode 1027. In this case, the second substrate 1040 can be transparent. The base layer 1030 can be formed on a rear surface of the transparent second substrate 1040.

The base layer 1030 forms a background against a pattern formed by a dye 1023 such that the pattern can be effectively identified when viewed from the outside and can be formed by including a fluorescent or phosphorescent substance or by including a dye or pigment with a specific color.

In this embodiment, since the base layer 1030 is disposed behind the light absorption layer 1025, the pattern formed by the dye 1023 can be effectively identified against its background when viewed from the front of the first substrate 1011.

Meanwhile, the dye-sensitized solar cell 1000 of the present embodiment can further include a metal coating layer (not shown), which is formed on a rear surface of the base layer 1030 and provides a reflective surface. In this case, the base layer 1030 can be translucent.

In this case, the sunlight transmitted through the translucent base layer 1030 can be reflected to the base layer 1030 by the metal coating layer (not shown). The light reflected by the metal coating layer (not shown) strikes a rear surface of the translucent base layer 1030 so that the base layer 1030 can be identified more clearly when viewed from the outside. This allows the pattern formed by the dye 1023 to be identified more clearly.

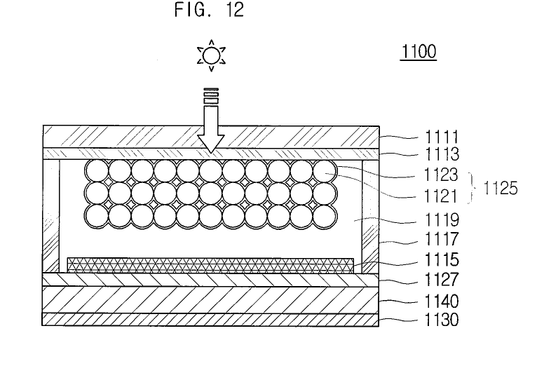

FIG. 12 briefly shows a structure of a dye-sensitized solar cell in accordance with still another embodiment of the present invention. Referring to FIG. 12, a dye-sensitized solar cell 1100 according to the present embodiment can be constituted by a first substrate 1111, a first electrode 1113, a second electrode 1127, a catalytic layer 1115, a light absorption layer 1125, an electrolyte 1119, a second substrate 1140 and a base layer 1130.

Compared to the dye-sensitized solar cell 500 of the previously described embodiment, the dye-sensitized solar cell 1100 of the present embodiment is different in that the positions of the second substrate 1140 and the base layer 1130 are different from those of the second substrate 540 and the base layer 530 of the dye-sensitized solar cell 500 of the previously described embodiment. Thus, the difference between the dye-sensitized solar cell 1100 of the present embodiment and the dye-sensitized solar cell 500 of the previously described embodiment will be mainly described hereinafter, and redundant descriptions are omitted.

In this embodiment, the second substrate 1140 can be formed on a rear surface of the second electrode 1127. In this case, the second substrate 1140 can be transparent. The base layer 1130 can be formed on a rear surface of the transparent second substrate 1140.

The base layer 1130 forms a background against a pattern formed by a dye 1123 such that the pattern can be effectively identified when viewed from the outside and can be formed by including a fluorescent or phosphorescent substance or by including a dye or pigment with a specific color.

In this embodiment, since the base layer 1130 is disposed behind the light absorption layer 1125, the pattern formed by the dye 1123 can be effectively identified against its background when viewed from the front of the first substrate 1111.

Meanwhile, the dye-sensitized solar cell 1100 of the present embodiment can further include a metal coating layer (not shown), which is formed on a rear surface of the base layer 1130 and provides a reflective surface.

Meanwhile, a dye-sensitized solar cell in accordance with certain embodiments described above can be used in a mobile device. That is, the mobile device can be constituted by a body (not shown) and a dye-sensitized solar cell, which is mounted on the body in accordance with the previously described embodiments of the present invention. Here, the mobile device collectively refers to mobile phones, laptop computers, PMPs, PDAs and the like.

By a mobile device, for example, a mobile phone, in which a dye-sensitized solar cell according to the above embodiments of the present invention is included, a pattern formed by a dye included in the dye-sensitized solar cell can be effectively viewed. This can improve the aesthetic attractiveness of the mobile phone that includes the dye-sensitized solar cell.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

As such, many embodiments other than those set forth above can be found in the appended claims.

What is claimed is:

1. A dye-sensitized solar cell comprising:
a first substrate being transparent;
a first electrode formed on a rear surface of the first substrate;
a second electrode formed apart from the first electrode, the second electrode facing the first electrode;
a catalytic layer formed on a rear surface of the first electrode;
a light absorption layer formed on a front surface of the second electrode, the light absorption layer including a dye which is absorbed into metal oxide such that the dye forms a specific pattern with the metal oxide;
an electrolyte interposed between the first electrode and the second electrode;
a base layer formed on a rear surface of the second electrode and configured to form a background against the pattern formed by the dye such that the pattern can be identified when viewed from the outside; and
a second substrate formed on a rear surface of the base layer.

2. The dye-sensitized solar cell of claim 1, wherein the base layer is formed by including a fluorescent or phosphorescent substance.

3. The dye-sensitized solar cell of claim 2, wherein the base layer is translucent and the second substrate is a metal substrate having a reflective surface formed on its front surface.

4. The dye-sensitized solar cell of claim 2, further comprising a secondary base layer formed on a rear surface of the second substrate,
wherein the base layer is translucent and the second substrate is transparent.

5. The dye-sensitized solar cell of claim 4, wherein the secondary base layer is formed by including a fluorescent or phosphorescent substance.

6. The dye-sensitized solar cell of claim 4, wherein the secondary base layer is formed by including a dye or pigment with a specific color.

7. The dye-sensitized solar cell of claim 2, further comprising a metal coating layer interposed between the base layer and the second substrate and configured to provide a reflective surface,
wherein the base layer is translucent.

8. The dye-sensitized solar cell of claim 2, further comprising a metal coating layer formed on a rear surface of the second substrate and configured to provide a reflective surface,
wherein the base layer is translucent and the second substrate is transparent.

9. The dye-sensitized solar cell of claim 1, wherein the base layer is formed by including a dye or pigment with a specific color.

10. The dye-sensitized solar cell of claim 9, wherein the base layer is translucent and the second substrate is a metal substrate having a reflective surface formed on its front surface.

11. The dye-sensitized solar cell of claim 9, further comprising a secondary base layer formed on a rear surface of the second substrate,
wherein the base layer is translucent and the second substrate is transparent.

12. The dye-sensitized solar cell of claim 11, wherein the secondary base layer is formed by including a fluorescent or phosphorescent substance.

13. The dye-sensitized solar cell of claim 11, wherein the secondary base layer is formed by including a dye or pigment with a specific color.

14. The dye-sensitized solar cell of claim 9, further comprising a metal coating layer interposed between the base layer and the second substrate and configured to provide a reflective surface,
wherein the base layer is translucent.

15. The dye-sensitized solar cell of claim 9, further comprising a metal coating layer formed on a rear surface of the second substrate and configured to provide a reflective surface,
wherein the base layer is translucent and the second substrate is transparent.

16. A dye-sensitized solar cell comprising:
a first substrate being transparent;
a first electrode formed on a rear surface of the first substrate;
a second electrode formed apart from the first electrode, the second electrode facing the first electrode;
a light absorption layer formed on a rear surface of the first electrode, the light absorption layer including a dye which is absorbed into metal oxide such that the dye forms a specific pattern with the metal oxide;
a catalytic layer formed on a front surface of the second electrode;
an electrolyte interposed between the first electrode and the second electrode;
a base layer formed on a rear surface of the second electrode and configured to form a background against the pattern formed by the dye such that the pattern can be identified when viewed from the outside; and
a second substrate formed on a rear surface of the base layer.

17. The dye-sensitized solar cell of claim 16, wherein the base layer is formed by including a dye or pigment with a specific color.

18. The dye-sensitized solar cell of claim 17, wherein the base layer is translucent and the second substrate is a metal substrate having a reflective surface formed on its front surface.

19. The dye-sensitized solar cell of claim 17, further comprising a secondary base layer formed on a rear surface of the second substrate,
wherein the base layer is translucent and the second substrate is transparent.

20. The dye-sensitized solar cell of claim 17, wherein the secondary base layer is formed by including a fluorescent or phosphorescent substance.

21. The dye-sensitized solar cell of claim 17, wherein the secondary base layer is formed by including a dye or pigment with a specific color.

22. The dye-sensitized solar cell of claim 17, further comprising a metal coating layer interposed between the base layer and the second substrate and configured to provide a reflective surface,
wherein the base layer is translucent.

23. The dye-sensitized solar cell of claim 17, further comprising a metal coating layer formed on a rear surface of the second substrate and configured to provide a reflective surface,
wherein the base layer is translucent and the second substrate is transparent.

24. A dye-sensitized solar cell comprising:
a first substrate being transparent;
a first electrode formed on a rear surface of the first substrate;
a second electrode formed apart from the first electrode, the second electrode facing the first electrode;
a light absorption layer interposed between the first electrode and the second electrode, the light absorption layer including a dye which is absorbed into metal oxide such that the dye forms a specific pattern with the metal oxide;
a catalytic layer interposed between the first electrode and the second electrode, the catalytic layer being formed apart from the light absorption layer, the catalytic layer facing the light absorption layer;
an electrolyte interposed between the first electrode and the second electrode; and
a second substrate formed on a rear surface of the second electrode and configured to form a background against the pattern formed by the dye such that the pattern can be identified when viewed from the outside.

25. The dye-sensitized solar cell of claim 24, wherein the second substrate is a metal substrate and has a colored reflective surface formed on its front surface.

26. A dye-sensitized solar cell comprising:
a first substrate being transparent;
a first electrode formed on a rear surface of the first substrate;
a second electrode formed apart from the first electrode, the second electrode facing the first electrode;
a catalytic layer formed on a rear surface of the first electrode;
a light absorption layer formed on a front surface of the second electrode, the light absorption layer including a dye which is absorbed into metal oxide such that the dye forms a specific pattern with the metal oxide;
an electrolyte interposed between the first electrode and the second electrode;
a second substrate formed on a rear surface of the second electrode, the second substrate being transparent; and
a base layer formed on a rear surface of the second electrode and configured to form a background against the pattern formed by the dye such that the pattern can be identified when viewed from the outside.

27. The dye-sensitized solar cell of claim 26, wherein the base layer is formed by including a fluorescent or phosphorescent substance.

28. The dye-sensitized solar cell of claim 26, wherein the base layer is formed by including a dye or pigment with a specific color.

29. A dye-sensitized solar cell comprising:
a first substrate being transparent;
a first electrode formed on a rear surface of the first substrate;
a second electrode formed apart from the first electrode, the second electrode facing the first electrode;
a light absorption layer formed on a rear surface of the first electrode, the light absorption layer including a dye which is absorbed into metal oxide such that the dye forms a specific pattern with the metal oxide;
a catalytic layer formed on a front surface of the second electrode;
an electrolyte interposed between the first electrode and the second electrode;
a second substrate formed on a rear surface of the second electrode, the second substrate being transparent; and
a base layer formed on a rear surface of the second electrode and configured to form a background against the pattern formed by the dye such that the pattern can be identified when viewed from the outside.

30. The dye-sensitized solar cell of claim 29, wherein the base layer is formed by including a dye or pigment with a specific color.

31. A mobile device comprising:
a body; and
a dye-sensitized solar cell in accordance with any one of claims 1, 16, 24, 26 and 29, the dye-sensitized solar cell being mounted on the body.
